(19) United States
(12) Patent Application Publication
(10) Pub. No.: US 2016/0005819 A1
(43) Pub. Date: Jan. 7, 2016

(54) SEMICONDUCTOR DEVICE

(71) Applicant: Renesas Electronics Corporation, Kawasaki-shi (JP)

(72) Inventors: Takahiro Kainuma, Kanagawa (JP); Takashi Igarashi, Kanagawa (JP); Hiroshi Inagawa, Kanagawa (JP); Takeshi Arai, Kanagawa (JP); Yuji Fujii, Kanagawa (JP); Takahiro Okamura, Ibaraki (JP); Hisashi Toyoda, Tokyo (JP)

(73) Assignee: Renesas Electronics Corporation

(21) Appl. No.: 14/738,852

(22) Filed: Jun. 13, 2015

(30) Foreign Application Priority Data
Jul. 2, 2014 (JP) 2014-137200

(51) Int. Cl. H01L 29/16; H01L 29/78; H01L 29/872; H01L 29/45; H01L 29/861

(52) U.S. Cl. CPC H01L 29/1608; H01L 29/45; H01L 29/861; H01L 29/872; H01L 29/7827; H01L 29/7802

(57) ABSTRACT

Contact resistance between a SiC substrate and an electrode is decreased. When a silicide layer is analyzed by Auger Electron Spectroscopy (AES) sputter in a direction from a titanium layer side to a SiC substrate side, sputtering time corresponding to a depth profile of the silicide layer is defined as tₛ. In this case, a depth profile of the silicide layer from the titanium layer side in a range of sputtering time from 0.4tₛ to tₛ contains a region where titanium atoms determined by the AES sputter accounts for 5 at % or more of all atoms determined by the AES sputter.

### CROSS-REFERENCE TO RELATED APPLICATIONS

The disclosure of Japanese Patent Application No. 2014-137200 filed on Jul. 2, 2014 including the specification, drawings and abstract is incorporated herein by reference in its entirety.

### BACKGROUND

The present invention relates to a semiconductor device, and provides a technique applicable to a semiconductor device including, for example, a silicon carbide (SiC) substrate.

A substrate for use in a semiconductor device may be required to have high withstand voltage. The SiC substrate may be used as such a substrate.

When the SiC substrate is used in a semiconductor device, an electrode, which is to be ohmically connected to the SiC substrate, may be provided. Japanese Unexamined Patent Application Publication No. 2010-86999 describes a method of forming such an electrode. In Japanese Unexamined Patent Application Publication No. 2010-86999, specifically, a nickel layer is first formed on a surface of a SiC substrate. Subsequently, the SiC substrate and the nickel layer are heated. Consequently, a silicide layer is formed in the surface of the SiC substrate. In this step, part of the nickel layer remains without contributing to formation of silicide. Subsequently, such a part of the nickel layer portion, which has not contributed to formation of silicide, is removed. Subsequently, a titanium layer is formed on the silicide layer. Subsequently, a metal layer (for example, nickel layer) is formed on the titanium layer.

### SUMMARY

The SiC substrate has good properties such as, for example, high withstand voltage. Various semiconductor devices (for example, a transistor and a diode) are currently formed using the SiC substrate and under investigation in order to use such properties. The investors have investigated a structure that decreases contact resistance between the SiC substrate and an electrode in order to allow such semiconductor devices to effectively operate. Other issues and novel features will be clarified from the description of this specification and the accompanying drawings.

According to one embodiment of the invention, there is provided a semiconductor device, in which a silicide layer containing nickel and titanium is provided in a surface of a SiC substrate. A metal layer is stacked on the silicide layer. When the silicide layer is analyzed by Auger Electron Spectroscopy (AES) sputter in a direction from a metal layer side to a SiC substrate side, sputtering time corresponding to a depth profile of the silicide layer is defined as tₛ. In this case, a depth profile of the silicide layer from the metal layer side in a range of sputtering time from 0.4tₛ to tₛ contains a region where titanium atoms determined by the AES sputter accounts for 5 at % or more of all atoms determined by the AES sputter.

According to the above-described one embodiment of the invention, contact resistance between the SiC substrate and the electrode is decreased.

### BRIEF DESCRIPTION OF THE DRAWINGS

FIG. 1 is a diagram illustrating a layer structure for use in a semiconductor device according to a first embodiment.

FIG. 2 is a diagram illustrating a method for forming the structure of the semiconductor device illustrated in FIG. 1.

FIG. 3 is a diagram illustrating the method for forming the structure of the semiconductor device illustrated in FIG. 1.

FIG. 4 is a diagram illustrating the method for forming the structure of the semiconductor device illustrated in FIG. 1.

FIG. 5 is a diagram illustrating a modification of the configuration of FIG. 3.

FIG. 6 is a diagram illustrating a layer structure for use in a semiconductor device according to a comparative example.

FIG. 7 is a diagram illustrating a method for forming the structure of the semiconductor device illustrated in FIG. 6.

FIG. 8 is a diagram illustrating the method for forming the structure of the semiconductor device illustrated in FIG. 6.

FIG. 9A is a graph illustrating a depth profile of the layer structure according to the first embodiment. FIG. 9B is a graph illustrating a depth profile of the layer structure according to the comparative example.

FIG. 10 is a diagram illustrating a configuration of a semiconductor device according to a second embodiment.

FIG. 11 is a diagram illustrating a modification of the configuration of FIG. 10.

FIG. 12 is a diagram illustrating a modification of the configuration of FIG. 11.

FIG. 13 is a diagram illustrating a configuration of a semiconductor device according to a third embodiment.

FIG. 14 is a diagram illustrating a modification of the configuration of FIG. 13.

FIG. 15 is a diagram illustrating a configuration of a semiconductor device according to a fourth embodiment.

### DETAILED DESCRIPTION

Hereinafter, some embodiments of the invention are described with reference to accompanying drawings. In all the drawings, like components are designated by like numerals, and duplicated description is appropriately omitted.

### First Embodiment

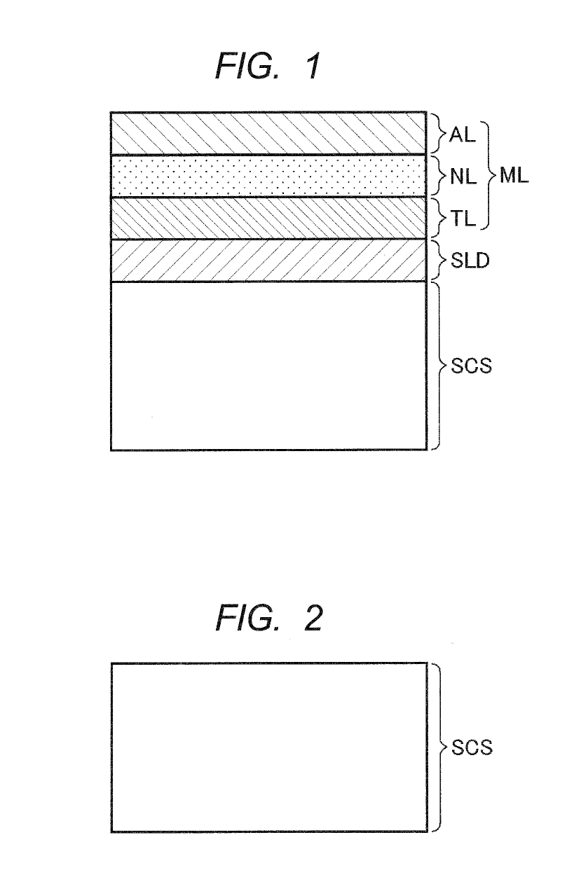

FIG. 1 is a diagram illustrating a layer structure for use in a semiconductor device according to a first embodiment. The semiconductor device includes a SiC substrate SCS, a silicide layer SLD, and a metal layer ML (a titanium layer TL, a nickel layer NL, and a gold layer AL). The SiC substrate SCS includes the silicide layer SLD in its surface. As described in detail later, the silicide layer SLD contains nickel (Ni) and titanium (Ti). The titanium layer TL, the nickel layer NL, and the gold layer AL are arranged in order of closeness to the silicide layer SLD. However, the layer structure of the metal layer ML is not limited to the exemplary structure illustrated in FIG. 1 (the titanium layer TL, the nickel layer NL, and the gold layer AL).

FIGS. 2 to 4 are each a diagram illustrating a method for forming the structure of the semiconductor device illustrated in FIG. 1. First, as illustrated in FIG. 2, the SiC substrate SCS is provided.

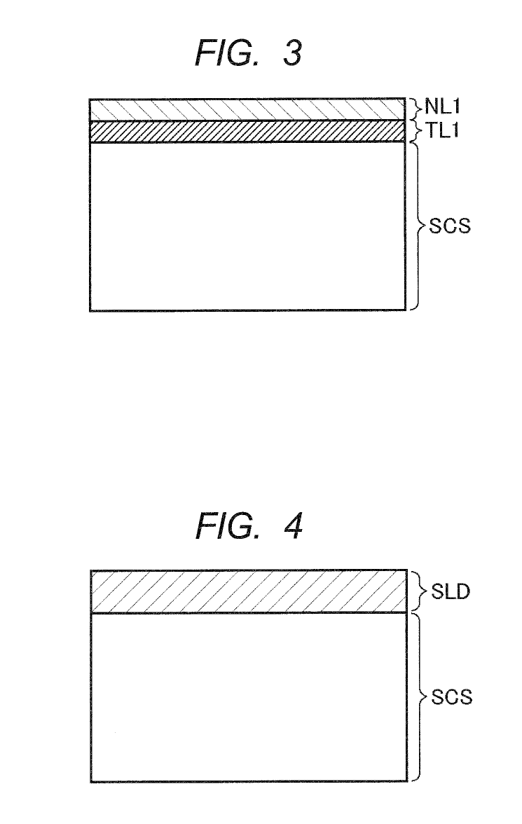

Subsequently, as illustrated in FIG. 3, the titanium layer TL1 is formed on the SiC substrate SCS by, for example, sputter. As described later, the titanium layer TL1 contributes to form the silicide layer SLD. The titanium layer TL1 has a thickness of, for example, 5 to 10 nm. Subsequently, the nickel layer NL1 is formed on the titanium layer TL1 by, for example, sputter. As described later, the nickel layer NL1 also contributes to form the silicide layer SLD. The nickel layer NL1 has a thickness of, for example, 5 to 200 nm. The nickel layer NL1 may not be directly formed on the titanium layer TL1. For example, the nickel layer NL1 may be formed over the titanium layer TL1 while a metal layer different from the nickel layer NL1 is provided therebetween.

Subsequently, as illustrated in FIG. 4, the silicide layer SLD is formed in the surface of the SiC substrate SCS. Specifically, the SiC substrate SCS, the titanium layer TL1, and the nickel layer NL1 (FIG. 3) are heated by, for example, laser anneal. Consequently, the silicide layer SLD is formed in the surface of the SiC substrate SCS. In this case, the SiC substrate SCS contains titanium (Ti) and nickel (Ni) that come from the titanium layer TL1 and the nickel layer NL1, respectively.

Subsequently, the titanium layer TL, the nickel layer NL, and the gold layer AL are formed in this order on the silicide layer SLD. In this way, the structure illustrated in FIG. 1 is formed.

FIG. 5 is a diagram illustrating a modification of the configuration of FIG. 3. As illustrated in FIG. 5, a titanium-nickel alloy layer TNL may be formed on the SiC substrate SCS by, for example, sputter. In this case, the silicide layer SLD can also be formed by heating the SiC substrate SCS and the titanium-nickel alloy layer TNL as illustrated in FIG. 4.

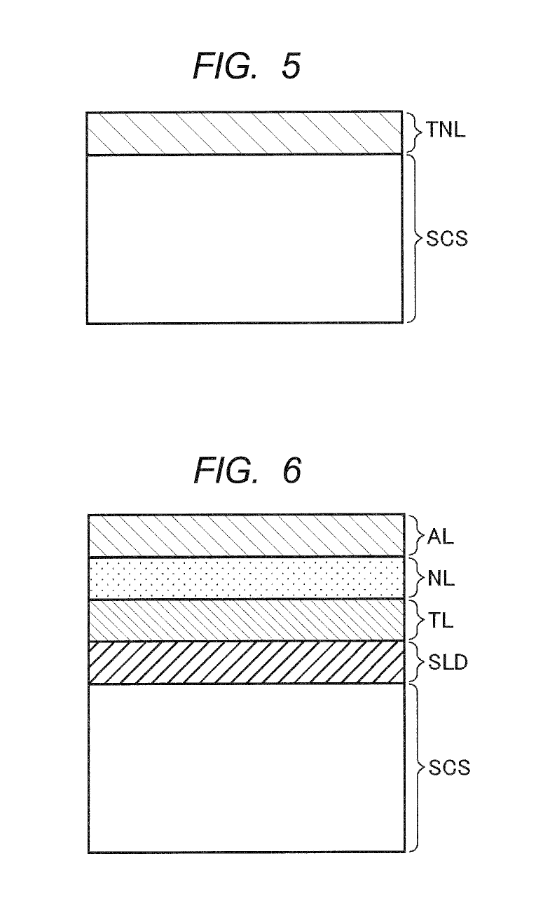

FIG. 6 is a diagram illustrating a layer structure for use in a semiconductor device according to a comparative example, and corresponds to FIG. 1 of the first embodiment. The semiconductor device includes the SiC substrate SCS, the silicide layer SLD, the titanium layer TL, the nickel layer NL, and the gold layer AL. The SiC substrate SCS includes the silicide layer SLD in its surface. As described in detail later, the silicide layer SLD contains nickel (Ni). The titanium layer TL, the nickel layer NL, and the gold layer AL are arranged in order of closeness to the silicide layer SLD.

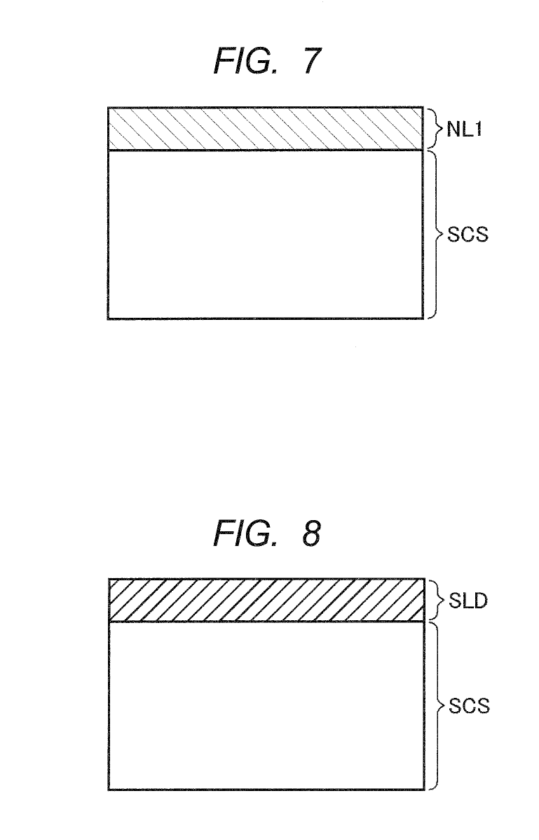

FIGS. 7 and 8 are each a diagram illustrating a method for forming the structure of the semiconductor device illustrated in FIG. 6. First, as with the first embodiment, the step illustrated in FIG. 2 is performed.

Subsequently, as illustrated in FIG. 7, the nickel layer NL1 is formed on the SiC substrate SCS. As described later, the nickel layer NL1 contributes to form the silicide layer SLD.

Subsequently, as illustrated in FIG. 8, the silicide layer SLD is formed in the surface of the SiC substrate SCS. Specifically, the SiC substrate SCS and the nickel layer NL1 (FIG. 7) are heated by, for example, laser anneal. Consequently, the silicide layer SLD is formed in the surface of the SiC substrate SCS. In this case, the SiC substrate SCS contains nickel (Ni) that comes from the nickel layer NL1.

Subsequently, the titanium layer TL, the nickel layer NL, and the gold layer AL are formed in this order on the silicide layer SLD. In this way, the structure illustrated in FIG. 6 is formed.

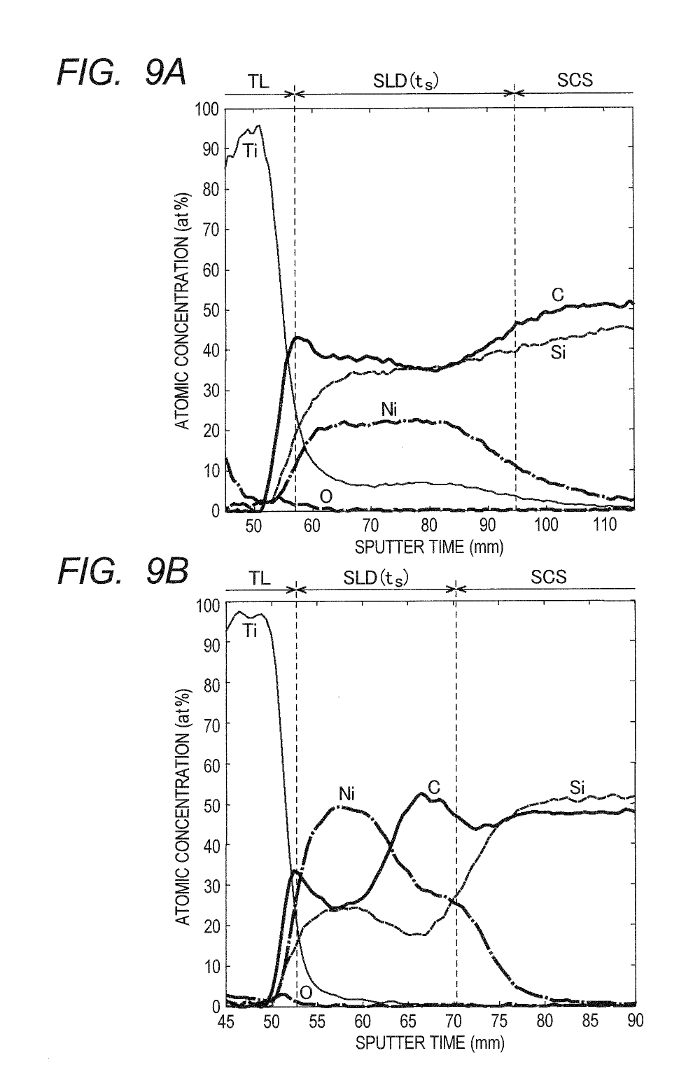

FIG. 9A is a graph illustrating a depth profile of the layer structure according to the first embodiment. FIG. 9B is a graph illustrating a depth profile of the layer structure according to the comparative example. The depth profiles illustrated in FIGS. 9A and 9B are each obtained through analysis of the silicide layer SLD by Auger Electron Spectroscopy (AES) sputter in a direction from a titanium layer TL side to the SiC substrate SCS. Argon (Ar) sputter is used for the AES sputter.

First, the first embodiment is described using FIG. 9A. In the exemplary case illustrated in FIG. 9A, a region (sputtering time: about 55 to 95 min), in which a nickel (Ni) spectrum has a value equal to or larger than the half the peak value, corresponds to the silicide layer SLD. A region (sputtering time: about 55 min or less) to the left of such a region corresponds to the titanium layer TL. A region (sputtering time: about 95 min or more) to the right of that region of the silicide layer SLD corresponds to the SiC substrate SCS. In the exemplary case illustrated in FIG. 9A, the width of that region (sputtering time: about 55 to 95 min) of the silicide layer SLD corresponds to the sputtering time tₛ corresponding to the depth profile of the silicide layer SLD.

In the exemplary case illustrated in FIG. 9A, the depth profile of the silicide layer SLD from the titanium layer TL side in a range of sputtering time from 0.4tₛ to tₛ contains a region where titanium (Ti) atoms determined by the AES sputter accounts for 5 at % or more of all atoms determined by the AES sputter. In other words, the silicide layer SLD contains a certain amount of titanium (Ti) on a side close to the SiC substrate SCS.

Through investigations, the inventors have found that the titanium (Ti) that the silicide layer SLD contains on the side close to the SiC substrate SCS (FIG. 9A) probably comes from the titanium layer TL1 (FIG. 3). In the first embodiment, as illustrated in FIGS. 3 and 4, the silicide layer SLD is formed while the SiC substrate SCS, the titanium layer TL1, and the nickel layer NL1 are arranged in this order. In other words, titanium (titanium layer TL1) is located on a side, which is close to the SiC substrate SCS, of the silicide layer SLD before formation of the silicide layer SLD. In such a case, even if the silicide layer SLD is formed in the surface of the SiC substrate SCS, a certain amount of titanium (Ti) probably remains on the side, which is close to the SiC substrate SCS, of the silicide layer SLD.

As described above, the nickel layer NL1 (FIG. 3) may not be directly formed on the titanium layer TL1 (FIG. 3). In such a case, for example, a metal layer, which is not the titanium layer TL1 or the nickel layer NL1, is located between the titanium layer TL1 and the nickel layer NL1. In this case, the silicide layer SLD may also contain titanium (Ti), which comes from the titanium layer TL, on the side close to the SiC substrate SCS. Furthermore, even if the titanium-nickel alloy layer TNL is provided as illustrated in FIG. 5, the silicide layer SLD may contain titanium (Ti), which comes from the titanium-nickel alloy layer TNL, on the side close to the SiC substrate SCS.

Furthermore, in the exemplary case illustrated in FIG. 9A, the depth profile of the silicide layer SLD from the titanium layer TL side in a range of sputtering time from 0.1tₛ to tₛ contains a region where nickel (Ni) atoms determined by the AES sputter accounts for 2 at % or more of all atoms determined by the AES sputter. In other words, the silicide layer SLD contains a certain amount of nickel (Ni) on the side close to the SiC substrate SCS. Through investigations, the inventors have found that such nickel (Ni) probably comes from the nickel layer NL1 (FIG. 3).

Furthermore, in the exemplary case illustrated in FIG. 9A, the depth profile of the silicide layer SLD from the titanium layer TL side in the range of sputtering time from 0.4tₛ to tₛ shows that the number of atoms of nickel (Ni) is larger than the number of atoms of titanium (Ti) in any region. Such a profile is achieved by controlling the thickness of each of the titanium layer TL1 and the nickel layer NL1 in the step illustrated in FIG. 3. In detail, the thickness of the nickel layer NL1 and the number of atoms of nickel contained in the nickel layer NL1 are controlled to be larger than the thickness of the titanium layer TL1 and the number of atoms of titanium contained in the titanium layer TL1, respectively.

However, the number relationship between the number of atoms of nickel (Ni) and the number of atoms of titanium (Ti) is not limited to the exemplary relationship in FIG. 9A. For example, the depth profile of the silicide layer SLD from the titanium layer TL side in the range of sputtering time from 0.4tₛ to tₛ may show that the number of atoms of nickel (Ni) is smaller than the number of atoms of titanium (Ti) in any region. Such a profile is achieved by controlling the thickness of each of the titanium layer TL1 and the nickel layer NL1 in the step illustrated in FIG. 3 in the same way as described above.

Furthermore, in the exemplary case illustrated in FIG. 9A, carbon (c), nickel (Ni), and titanium (Ti) are each uniformly dispersed in a central region of the silicide layer SLD (sputtering time: about 55 to 95 min). Specifically, the depth profile of the silicide layer SLD from the titanium layer TL side in a range of sputtering time from 0.25tₛ to 0.75tₛ shows that a difference between the maximum and the minimum of the number of atoms (atom concentration) of carbon (C) is 10% or less of the arithmetic mean of the maximum and the minimum. Similarly, the depth profile shows that a difference between the maximum and the minimum of the number of atoms (atom concentration) of nickel (Ni) is 10% or less of the arithmetic mean of the maximum and the minimum. Similarly, the depth profile shows that a difference between the maximum and the minimum of the number of atoms (atom concentration) of titanium (Ti) is 10% or less of the arithmetic mean of the maximum and the minimum.

Subsequently, a comparative example is described using FIG. 9B. In the exemplary case illustrated in FIG. 9B, a region (sputtering time: about 52.5 to 70 min), in which a nickel (Ni) spectrum has a value equal to or larger than the half the peak value, corresponds to the silicide layer SLD. A region (sputtering time: about 52.5 min or less) to the left of such a region corresponds to the titanium layer TL. A region (sputtering time: about 70 min or more) to the right of that region of the silicide layer SLD corresponds to the SiC substrate SCS.

In the exemplary case illustrated in FIG. 9B, the width of the above-described region of the silicide layer SLD (sputtering time: about 52.5 to 70 min) corresponds to the sputtering time tₛ corresponding to the depth profile of the silicide layer SLD. In the case illustrated in FIG. 9B, the depth profile of the silicide layer SLD from the titanium layer TL side in a range of sputtering time from 0.4tₛ to tₛ shows that the number of atoms of titanium determined by the AES sputter is substantially zero. In other words, the silicide layer SLD contains substantially no titanium (Ti) on the side close to the SiC substrate SCS.

In the comparative example, as illustrated in FIGS. 7 and 8, the silicide layer SLD is formed while the nickel layer NL1 is provided on the SiC substrate SCS. In other words, the silicide layer SLD is formed without the titanium layer that allows the silicide layer SLD to significantly contain titanium (Ti). Consequently, in the comparative example, the silicide layer SLD contains substantially no titanium (Ti) on the side close to the SiC substrate SCS.

Furthermore, in the case illustrated in FIG. 9B, atom concentration of carbon (C) in the silicide layer SLD (sputtering time: about 52.5 to 70 min) greatly varies compared with the case illustrated in FIG. 9A. Furthermore, the atom concentration of carbon (C) in the silicide layer SLD has a peak on the side close to the SiC substrate SCS. Such a peak suggests that carbon (C) is locally distributed in the region, which is close to the SiC substrate SCS, of the silicide layer SLD.

Carbon may have an electric resistivity higher than the silicide layer SLD. In such a case, the region in which carbon is locally distributed has a relatively high electric resistance. Local distribution of carbon thus results in such high electric resistance, and therethrough may affect operation of the semiconductor device including the SiC substrate SCS.

Through investigations, the inventors have found that the carbon (C) locally distributed in the silicide layer SLD on the side close to the SiC substrate SCS (FIG. 9B) comes from carbon (C) contained in the SiC substrate SCS. Such carbon (C) may be precipitated during, for example, anneal for forming the silicide layer SLD (as exemplarily shown in FIG. 8).

FIGS. 9A and 9B are now compared with each other. In FIG. 9A, carbon (C) is inhibited from being locally distributed in a partial region of the silicide layer SLD. In FIG. 9B, carbon (C) is locally distributed in the silicide layer SLD on the side close to the SiC substrate SCS. Through investigations, the inventors have found that titanium (Ti) contained in the silicide layer SLD probably inhibits local distribution of carbon (C) in the first embodiment.

In detail, as described above, the silicide layer SLD in the first embodiment contains a significant amount of titanium (Ti) on the side close to the SiC substrate SCS (FIG. 9A). In the first embodiment, therefore, local distribution of carbon (C) is probably inhibited. In the comparative example, such a significant amount of titanium (Ti) is not contained in the silicide layer SLD on the side close to the SiC substrate SCS (FIG. 9B). In the comparative example, therefore, local distribution of carbon (C) is probably not inhibited.

Through investigations, the inventors have concluded that titanium (Ti) possibly inhibits local distribution of carbon (C) in the following manner. Anneal (heating) is performed for forming the silicide layer SLD in each of the first embodiment and the comparative example. Consequently, carbon (C) is precipitated from the SiC substrate SCS into the silicide layer SLD. In the first embodiment, as described above, the silicide layer SLD contains the significant amount of titanium (Ti). In general, titanium (Ti) is readily combined with carbon (C). Hence, in the first embodiment, when carbon (C) is precipitated from the SiC substrate SCS, the carbon (C) combines with titanium (Ti) contained in the silicide layer SLD. Such carbon (C) together with titanium (Ti) is substantially evenly diffused in the silicide layer SLD. Consequently, local distribution of carbon (C) is inhibited.

In the comparative example, the silicide layer SLD does not contain the significant amount of titanium (Ti). Hence, when carbon (C) is precipitated from the SiC substrate SCS, the carbon (C) scarcely combines with titanium (Ti). In this case, carbon (C) may scarcely diffuse in the silicide layer SLD. Consequently, carbon (C) is locally distributed in the silicide layer SLD on the side close to the SiC substrate SCS.

Furthermore, in FIG. 9A, nickel (Ni) is substantially evenly dispersed in the silicide layer SLD. In FIG. 9B, nickel (Ni) is locally distributed in the silicide layer SLD on a side close to the titanium layer TL.

Through investigations, the inventors have concluded that a difference possibly occurs between the first embodiment and the comparative example because of the following reason. The region in which carbon is locally distributed may block diffusion of nickel. In the first embodiment, carbon is inhibited from being locally distributed in some region of the silicide layer SLD. This substantially eliminates blocking of nickel diffusion by local distribution of carbon. In the comparative example, carbon is locally distributed in the silicide layer SLD on the side close to the SiC substrate SCS. Consequently, nickel that comes from the nickel layer NL1 (FIG. 7) may not be diffused to the SiC substrate SCS side.

As described above, according to the first embodiment, the silicide layer SLD contains the significant amount of titanium on the side close to the SiC substrate SCS. This inhibits carbon contained in the SiC substrate SCS from being locally distributed in some region of the silicide layer SLD.

### Second Embodiment

FIG. 10 is a diagram illustrating a configuration of a semiconductor device according to a second embodiment. The semiconductor device includes a diode. The semiconductor device is configured with the layer structure illustrated in FIG. 1. Specifically, the semiconductor device includes the SiC substrate SCS, a first-conduction-type semiconductor layer NSL, a second-conduction-type region PR, a first electrode EL1, and a second electrode EL2. The SiC substrate SCS and the first electrode EL1 are collectively configured with the layer structure illustrated in FIG. 1.

In the exemplary configuration illustrated in FIG. 10, the first conduction type is the n type, while the second conduction type is the p type. The first conduction type and the second conduction type, however, may be the p type and the n type, respectively. Hereinafter, description is made assuming that the first conduction type is the n type while the second conduction type is the p type.

The SiC substrate SCS has a first surface and a second surface opposed to each other. The first electrode EL1 is located on a first surface side. The second electrode EL2 is located on a second surface side. As described in detail later, in the configuration illustrated in FIG. 10, the first electrode EL1 serves as a cathode of the diode. The second electrode EL2 serves as an anode of the diode. In other words, the diode is designed such that current flows in a thickness direction of the SiC substrate SCS. In the configuration illustrated in FIG. 10, the SiC substrate SCS is an n⁺ substrate (first-conduction-type substrate).

The SiC substrate SCS has a silicide layer SLD on the first surface. The first electrode EL1 is stacked on the silicide layer SLD. The first electrode EL1 corresponds to the metal layer ML (the titanium layer TL, the nickel layer NL, and the gold layer AL) illustrated in FIG. 1. In this way, the layer structure illustrated in FIG. 1 is used in the configuration illustrated in FIG. 10. In such a configuration, the first electrode EL1 is coupled to the SiC substrate SCS via the silicide layer SLD. This allows the first electrode EL1 to be ohmically connected to the SiC substrate SCS.

The first-conduction-type semiconductor layer NSL is provided on the second surface of the SiC substrate SCS. The first-conduction-type semiconductor layer NSL is an epitaxial layer (such as a SiC epitaxial layer or a GaN epitaxial layer), which is formed with the SiC substrate SCS as a base material, for example. In the configuration illustrated in FIG. 10, the first-conduction-type semiconductor layer NSL is an n⁻ layer. The first-conduction-type semiconductor layer NSL has an impurity concentration lower than that of the SiC substrate SCS.

The second-conduction-type region PR is provided in the surface of the first-conduction-type semiconductor layer NSL. In this configuration, a pn junction is formed at an interface between the second-conduction-type region PR and the first-conduction-type semiconductor layer NSL. The diode is formed with such a pn junction.

An insulating layer DL is provided on the first-conduction-type semiconductor layer NSL. The insulating layer DL is formed of, for example, a silicon oxide (SiO₂) film or a silicon nitride (SiN) film. For example, the insulating layer DL serves as a protective layer that protects the surface of the first-conduction-type semiconductor layer NSL. The insulating layer DL has an opening that includes at least part of the second-conduction-type region PR therein in a plan view. As described later, the opening is filled with the second electrode EL2.

The second electrode EL2 is provided on the first-conduction-type semiconductor layer NSL. The second electrode EL2 is formed of a metal that forms an ohmic junction with the second-conduction-type region PR. When the second-conduction-type region PR is comprised of p-type SiC, a metal such as titanium (Ti) can be used as such a metal.

In the configuration illustrated in FIG. 10, the second electrode EL2 has a portion that overlaps with the opening in a plan view and fills the opening of the insulating layer DL. On the other hand, a region of the second electrode EL2 outside such a portion is located on the insulating layer DL. In this case, the region of the second electrode EL2 outside that portion functions as a field plate. An electric field may be concentrated in a region below the insulating layer DL. The above-described field plate relieves such electric-field concentration.

As described above, according to the second embodiment, the pn junction diode is configured with the SiC substrate SCS. In the diode, the layer structure illustrated in FIG. 1 is used for the electrode (first electrode EL1) to be coupled to the SiC substrate SCS. In this configuration, as with the first embodiment, local distribution of carbon is inhibited by the silicide layer (silicide layer SLD) contained in the layer structure illustrated in FIG. 1. Consequently, on resistance of the diode can be lowered.

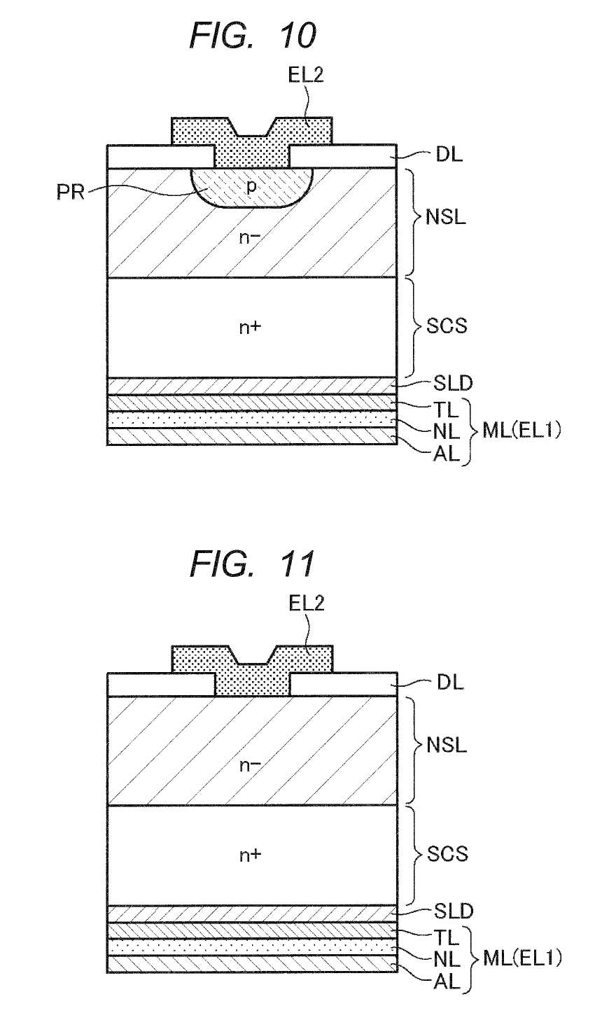

FIG. 11 is a diagram illustrating a modification of the configuration of FIG. 10. As illustrated in FIG. 11, the semiconductor device may have a Schottky barrier diode (SBD). Specifically, in the exemplary configuration illustrated in FIG. 11, the second-conduction-type region PR (FIG. 10) is not formed in the surface of the first-conduction-type semiconductor layer NSL. The second electrode EL2 is formed of a metal that forms a Schottky junction with the first-conduction-type semiconductor layer NSL. In this configuration, the SBD is formed across an interface between the second electrode EL2 and the first-conduction-type semiconductor layer NSL. When the first-conduction-type semiconductor layer NSL is comprised of n-type SiC, a metal such as titanium (Ti) can be used as the metal.

In the configuration illustrated in FIG. 11, on resistance of the diode (SBD) can also be lowered as with the second embodiment.

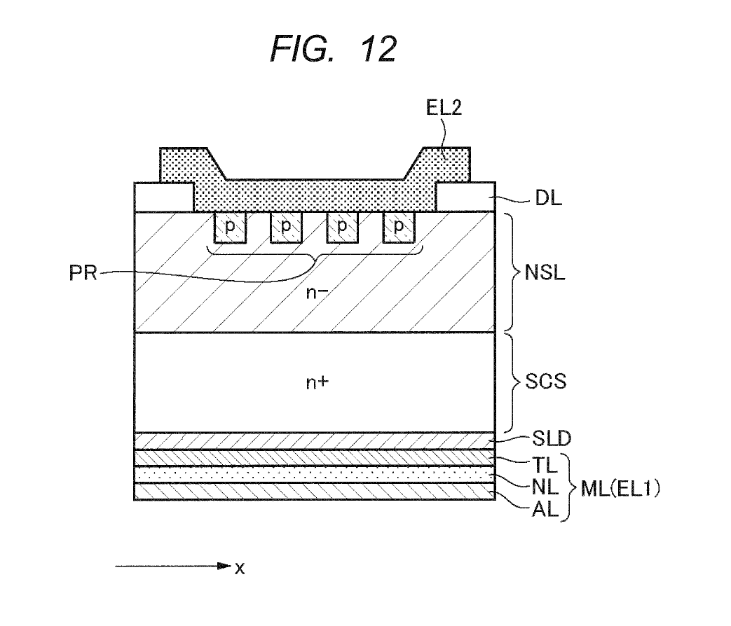

FIG. 12 is a diagram illustrating a modification of the configuration of FIG. 11. As illustrated in FIG. 12, the semiconductor device may include a junction barrier Schottky diode (JBS). In the JBS diode, as described later, SBD is configured with the first-conduction-type semiconductor layer NSL, and a plurality of second-conduction-type regions PR are provided in the first-conduction-type semiconductor layer NSL.

In detail, in the exemplary configuration illustrated in FIG. 12, the second-conduction-type regions PR are provided in the surface of the first-conduction-type semiconductor layer NSL. Each second-conduction-type region PR forms a pn junction with the first-conduction-type semiconductor layer NSL. The second-conduction-type regions PR are arranged along a first direction (x-axis direction in FIG. 12) in a plan view.

The second electrode EL2 is provided on the first-conduction-type semiconductor layer NSL. In the configuration illustrated in FIG. 12, the second electrode EL2 spans the second-conduction-type regions PR. The second electrode EL2 forms a Schottky junction with the first-conduction-type semiconductor layer NSL between the second-conduction-type regions PR adjacent to each other. Consequently, the SBD is formed across an interface between the second electrode EL2 and a region, in which no second-conduction-type region PR is provided, of the first-conduction-type semiconductor layer NSL.

In the JBS diode, when forward bias is applied, the SBD performs rectifying action. When reverse bias is applied, SBD is in general large in leakage current. In the JBS diode, the pn junction is configured of the plurality of second-conduction-type regions PR and the first-conduction-type semiconductor layer NSL. In such a configuration, when reverse bias is applied, a depleted layer is formed around each second-conduction-type region PR. In this case, the region of the first-conduction-type semiconductor layer NSL is allowed to be completely depleted, the region being located between the second-conduction-type regions PR adjacent to each other. The JBS diode can be suppressed in leakage current by such a depleted layer even if reverse bias is applied thereto.

In the configuration illustrated in FIG. 12, on resistance of the diode (SBD) can also be lowered as with the second embodiment.

### Third Embodiment

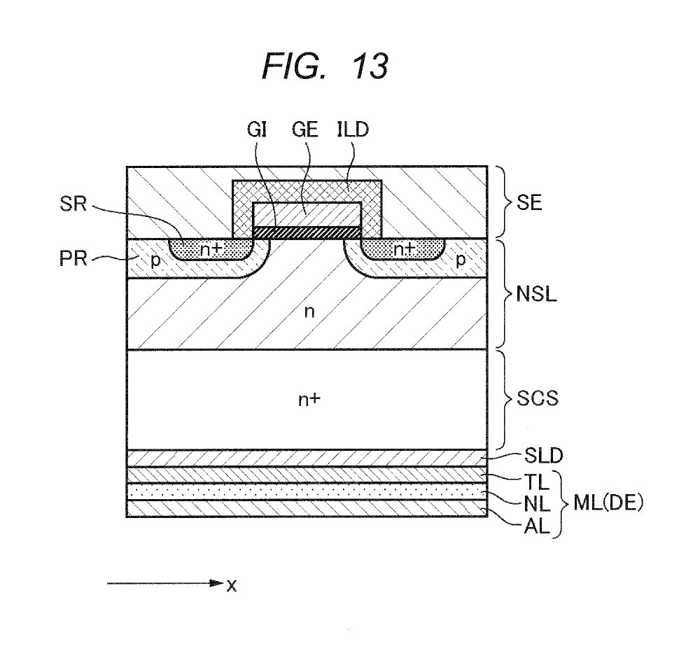

FIG. 13 is a diagram illustrating a configuration of a semiconductor device according to a third embodiment. The semiconductor device includes double-diffused MOS (DMOS). The semiconductor device is configured with the layer structure illustrated in FIG. 1. Specifically, the semiconductor device includes the SiC substrate SCS, the first-conduction-type semiconductor layer NSL, the second-conduction-type regions PR, source regions SR, a gate electrode GE, a drain electrode DE, and a source electrode SE. The SiC substrate SCS and the drain electrode DE are collectively configured with the layer structure illustrated in FIG. 1.

The SiC substrate SCS has a first surface and a second surface opposed to each other. The drain electrode DE is located on a first surface side. The gate electrode GE and the source electrode SE are located on a second surface side. In the exemplary configuration illustrated in FIG. 13, the SiC substrate SCS is an n⁺ substrate (first-conduction-type substrate).

The SiC substrate SCS has a silicide layer SLD on the first surface. The drain electrode DE is stacked on the silicide layer SLD. The drain electrode DE corresponds to the metal layer ML (the titanium layer TL, the nickel layer NL, and the gold layer AL) illustrated in FIG. 1. In this way, the layer structure illustrated in FIG. 1 is used in the configuration illustrated in FIG. 13. In such a configuration, the drain electrode DE is coupled to the SiC substrate SCS via the silicide layer SLD. This allows the drain electrode DE to be ohmically connected to the SiC substrate SCS.

The first-conduction-type semiconductor layer NSL is provided on the second surface of the SiC substrate SCS. The first-conduction-type semiconductor layer NSL is an epitaxial layer (such as a SiC epitaxial layer or a GaN epitaxial layer), which is formed with the SiC substrate SCS as a base material, for example. In the configuration illustrated in FIG. 13, the first-conduction-type semiconductor layer NSL is an n⁻ layer. The first-conduction-type semiconductor layer NSL has an impurity concentration lower than that of the SiC substrate SCS.

The second-conduction-type regions PR are provided in the surface of the first-conduction-type semiconductor layer NSL. In the configuration illustrated in FIG. 13, two second-conduction-type regions PR are opposed to each other along a first direction (x-axis direction in FIG. 13) in a plan view. As described later, the gate electrode GE is located between the two second-conduction-type regions PR.

The source region SR is provided in the surface of each second-conduction-type region PR. The source region SR is a first-conduction-type region (n⁺ region). In the configuration illustrated in FIG. 13, the source region SR is shallower than the second-conduction-type region PR.

A gate insulating film GI is provided on the first-conduction-type semiconductor layer NSL. In the configuration illustrated in FIG. 13, the gate insulating film GI spans the opposed second-conduction-type regions PR. The gate insulating film GI is formed of, for example, a silicon oxide (SiO₂) film.

The gate electrode GE is provided on the gate insulating film GI. The gate electrode GE thus spans the opposed second-conduction-type regions PR. The gate electrode GE is formed of, for example, polysilicon. Furthermore, in the configuration illustrated in FIG. 13, the gate electrode GE is covered with an interlayer insulating film ILD. The interlayer insulating film ILD is formed of, for example, a silicon oxide (SiO₂) film.

The source electrode SE is provided over the second-conduction-type regions PR. In this configuration, the source electrode SE includes at least some of the source regions SR therein in a plan view. Consequently, the source electrode SE can be electrically coupled to each source region SR. The source electrode SE is formed of a metal that forms an ohmic junction with the source region SR. Specifically, when the source region SR is comprised of n-type SiC, the source electrode SE is formed of, for example, titanium (Ti). In the configuration illustrated in FIG. 13, the source electrode SE covers the interlayer insulating film ILD and the first-conduction-type semiconductor layer NSL.

As described above, according to the third embodiment, the DMOS is configured with the SiC substrate SCS. In the DMOS, the layer structure illustrated in FIG. 1 is used for the electrode (drain electrode DE) to be coupled to the SiC substrate SCS. In this configuration, as with the first embodiment, local distribution of carbon is inhibited by the silicide layer (silicide layer SLD) contained in the layer structure illustrated in FIG. 1. Consequently, on resistance of the DMOS can be lowered.

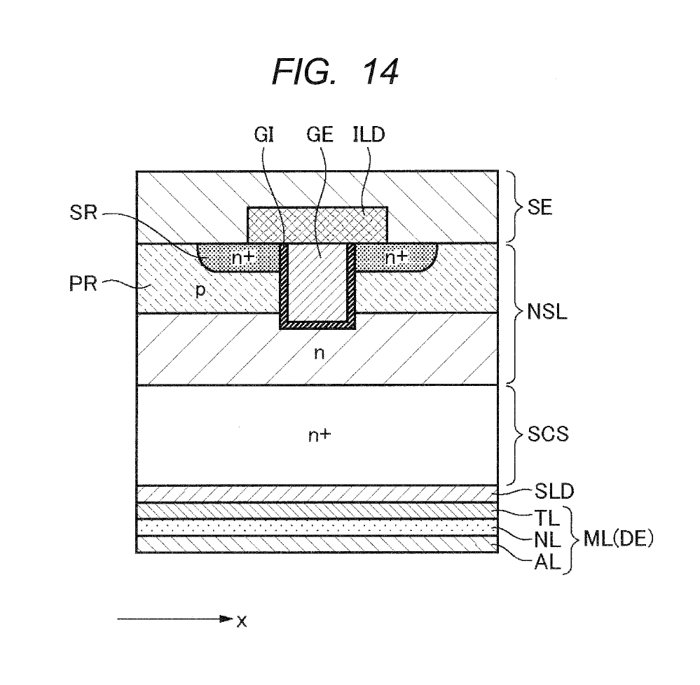

FIG. 14 is a diagram illustrating a modification of the configuration of FIG. 13. As illustrated in FIG. 14, the gate electrode GE may be buried in the first-conduction-type semiconductor layer NSL. In other words, the DMOS illustrated in FIG. 13 may be trench DMOS.

In detail, the first-conduction-type semiconductor layer NSL has a trench between the opposed second-conduction-type regions PR. The gate insulating film GI is provided along the bottom and the inner side face of the trench. Furthermore, the trench is filled with the gate electrode GE. In the exemplary configuration illustrated in FIG. 14, the trench is deeper than each source region SR and each second-conduction-type region PR.

In the configuration illustrated in FIG. 14, on resistance of the DMOS can also be lowered as with the third embodiment.

### Fourth Embodiment

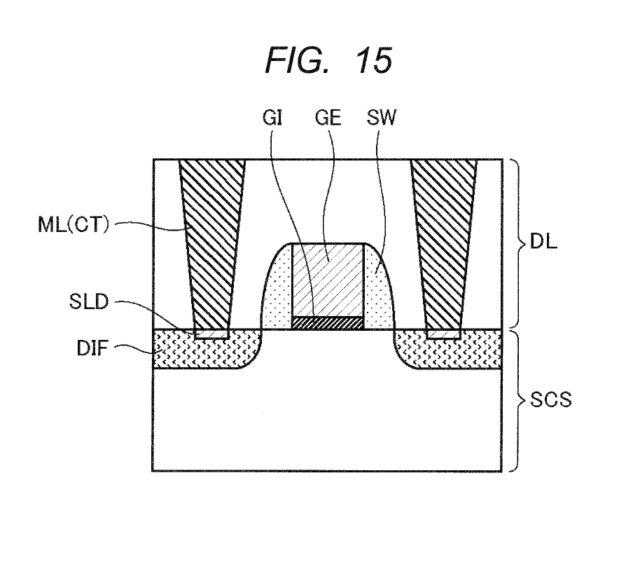

FIG. 15 is a diagram illustrating a configuration of a semiconductor device according to a fourth embodiment. The semiconductor device includes planar MOS. The semiconductor device is configured with the layer structure illustrated in FIG. 1. As described in detail later, however, the exemplary configuration illustrated in FIG. 15 is different in material configuring the metal layer ML from the configuration illustrated in FIG. 1. Specifically, the semiconductor device includes the SiC substrate SCS, diffusion layers DIF, the gate electrode GE, the insulating layer DL, and contacts CT. The SiC substrate SCS and each contact CT are collectively configured with the layer structure illustrated in FIG. 1.

In detail, the gate insulating film GI is provided on the surface of the SiC substrate SCS. The gate electrode GE is provided on the gate insulating film GI. A sidewall SW is provided on the side face of the gate electrode GE. The gate insulating film GI is formed of, for example, a silicon oxide (SiO₂) film. The gate electrode GE is formed of, for example, polysilicon. The sidewall SW is formed of, for example, a silicon oxide (SiO₂) film or a silicon nitride (SiN) film.

The diffusion layers DIF are provided in the surface of the SiC substrate SCS. In the configuration illustrated in FIG. 15, the two diffusion layers DIF are opposed to each other across the gate electrode GE. Each diffusion layer DIF serves as one of a source and a drain. The diffusion layer DIF includes, in its surface, the silicide layer SLD illustrated in FIG. 1.

The insulating layer DL is provided over the SiC substrate SCS, the gate electrode GE, and the sidewall SW so as to cover the SiC substrate SCS, the gate electrode GE, and the sidewall SW. The insulating layer DL is formed of, for example, a silicon oxide (SiO₂) film or a low-k material (for example, SiCOH).

The contacts CT are buried in the insulating layer DL. In the configuration illustrated in FIG. 15, each contact CT is provided on each diffusion layer DIF. The contact CT is coupled to the diffusion layer DIF while penetrating through the insulating layer DL. In this configuration, the lower end of the contact CT is coupled to the diffusion layer DIF via the silicide layer SLD illustrated in FIG. 1. In other words, the contact CT corresponds to the metal layer ML in the configuration illustrated in FIG. 1. The contact CT is formed of, for example, tungsten (W) or copper (Cu).

As described above, according to the fourth embodiment, the planar MOS is configured with the SiC substrate SCS. In the MOS, the silicide layer SLD illustrated in FIG. 1 is used as the silicide layer (silicide layer SLD) that allows the contact CT to be coupled to the SiC substrate SCS (diffusion layer DIF). In this configuration, as with the first embodiment, local distribution of carbon is inhibited by the silicide layer SLD. Consequently, on resistance of the MOS can be lowered.

Although the invention achieved by the inventors has been specifically described according to some embodiments thereof hereinbefore, the invention should not be limited thereto, and it will be appreciated that various modifications or alterations thereof may be made within the scope without departing from the gist of the invention.

What is claimed is:

1. A semiconductor device, comprising:
a SiC substrate;
a silicide layer provided in a surface of the SiC substrate, and containing nickel and titanium; and
a metal layer stacked over the silicide layer,
wherein, in the case where the silicide layer is analyzed by Auger Electron Spectroscopy (AES) sputter in a direction from a side of the metal layer to a side of the SiC substrate, when sputtering time corresponding to a depth profile of the silicide layer is defined as tₛ, a depth profile of the silicide layer from the metal layer side in a range of sputtering time from 0.4tₛ to tₛ contains a region where titanium atoms determined by the AES sputter accounts for 5 at % or more of all atoms determined by the AES sputter.

2. The semiconductor device according to claim 1, wherein a depth profile of the silicide layer from the metal layer side in a range of sputtering time from 0.1tₛ to tₛ contains a region where nickel atoms determined by the AES sputter accounts for 2 at % or more of all atoms determined by the AES sputter

3. The semiconductor device according to claim 2, wherein the depth profile of the silicide layer from the metal layer side in the range of sputtering time from 0.4tₛ to tₛ shows that the number of atoms of nickel determined by the AES sputter is larger than the number of atoms of titanium determined by the AES sputter in any region.

4. The semiconductor device according to claim 1, wherein a depth profile of the silicide layer from the metal layer side in a range of sputtering time from 0.25tₛ to 0.75tₛ shows that
a difference between the maximum and the minimum of the number of atoms of carbon determined by the AES sputter is 10% or less of the arithmetic mean of the maximum and the minimum,
a difference between the maximum and the minimum of the number of atoms of nickel determined by the AES sputter is 10% or less of the arithmetic mean of the maximum and the minimum, and
a difference between the maximum and the minimum of the number of atoms of titanium determined by the AES sputter is 10% or less of the arithmetic mean of the maximum and the minimum.

5. The semiconductor device according to claim 1,
wherein the SiC substrate includes:
a first surface having the silicide layer thereover; and
a second surface located on a side opposite to the first surface, and
wherein the semiconductor device further comprises:
a first electrode located on a side of the first surface, and corresponding to the metal layer;
a semiconductor layer located on a side of the second surface;
a second electrode opposed to the second surface with the semiconductor layer interposed therebetween; and
a diode configured of the first electrode, the semiconductor layer, and the second electrode.

6. The semiconductor device according to claim 5, further comprising a second-conduction-type region provided over a surface of the semiconductor layer, the semiconductor layer being of a first conduction type,
wherein the diode has a pn junction formed of the semiconductor layer and the second-conduction-type region.

7. The semiconductor device according to claim 5,
wherein the second electrode is comprised of a metal that forms a Schottky junction with the semiconductor layer, and
wherein the diode has a Schottky junction formed of the second electrode and the semiconductor layer.

8. The semiconductor device according to claim 7,
wherein the semiconductor device includes:
a semiconductor layer of a first-conduction-type;
a plurality of second-conduction-type regions provided in a surface of the semiconductor layer and arranged in a first direction in a plan view, each of the second-conduction-type regions forming a pn junction with the semiconductor layer, and
wherein the second electrode spans the second-conduction-type regions, and forms a Schottky junction with the semiconductor layer between the second-conduction-type regions adjacent to each other.

9. The semiconductor device according to claim 1,
wherein the SiC substrate includes:
a first surface having the silicide layer thereover; and
a second surface located on a side opposite to the first surface, and
wherein the semiconductor device further comprises:
a drain electrode located on a side of the first surface, and corresponding to the metal layer;
a semiconductor layer located on a side of the second surface;
a gate electrode located on a surface of the semiconductor layer, or buried in the surface of the semiconductor layer; and
a source provided on the surface of the semiconductor layer.

10. The semiconductor device according to claim 1, further comprising:
a gate electrode located on the SiC substrate;
diffusion layers provided in the SiC substrate so as to be formed into a source and a drain, each of the diffusion layers having a surface having the silicide layer therein;
an insulating layer covering the SiC substrate and the gate electrode; and
contacts that are buried in the insulating layer so as to be coupled to the diffusion layers, each of the contacts corresponding to the metal layer.
